(19) United States
(12) Patent Application Publication
(10) Pub. No.: US 2026/0173623 A1
(43) Pub. Date: Jun. 18, 2026

(54) DISPLAY PANEL AND MANUFACTURING METHOD THEREOF

(71) Applicant: AUO Corporation, Hsinchu City (TW)

(72) Inventors: Fu-Wei Chan, Hsinchu City (TW); Kai Hung Hsu, Hsinchu City (TW); Sheng-Chin Wang, Hsinchu City (TW); Kuan-Hsun Chen, Hsinchu City (TW)

(73) Assignee: AUO Corporation, Hsinchu City (TW)

(21) Appl. No.: 19/303,383

(22) Filed: Aug. 19, 2025

(30) Foreign Application Priority Data
Dec. 12, 2024 (TW) 113148518

(51) Int. Cl. H10H 29/853; H10H 29/01; H10H 29/85

(52) U.S. Cl. CPC H10H 29/853; H10H 29/0362; H10H 29/0364; H10H 29/857

(57) ABSTRACT

A display panel of the disclosure includes a substrate, a plurality of light emitting devices, a plurality of pads and an encapsulation layer. The substrate is provided with a display area and a pad area. The plurality of light emitting devices are disposed in the display area of the substrate. The plurality of pads are disposed in the pad area of the substrate. The encapsulation layer covers the plurality of light emitting devices and does not cover the plurality of pads. The encapsulation has a warped portion adjacent to the pad area. A gap is provided between the warped portion and a substrate surface of the substrate. The gap has a gap height along a normal direction of the substrate surface. The gap height increases as it approaches the plurality of pads. A manufacturing method of the display panel is also provided.

### CROSS-REFERENCE TO RELATED APPLICATION

This application claims the priority benefit of Taiwan application serial no. 113148518, filed on December 12, 2024. The entirety of the above-mentioned patent application is hereby incorporated by reference herein and made a part of this specification.

### BACKGROUND

### TECHNICAL FIELD

The disclosure relates to a display panel and a manufacturing method thereof, and particularly relates to a display panel with an encapsulation layer and a manufacturing method thereof.

### DESCRIPTION OF RELATED ART

To enhance environmental resistance, the light emitting devices on a self-emissive display panel are typically covered with an encapsulation layer to block the intrusion of moisture and oxygen from the environment. However, the encapsulation layer formed during the manufacturing process tends to extend over a pad area located adjacent to the display area, thereby preventing the pads located in the pad area and used for electrical testing or for bonding with a circuit board from properly performing their intended functions.

### SUMMARY

The disclosure provides a display panel with improved bonding yield and electrical test yield in the back-end manufacturing process.

The disclosure provides a manufacturing method of a display panel, which may significantly improve the usability of the pads after the encapsulation process.

A display panel of the disclosure includes a substrate, a plurality of light emitting devices, a plurality of pads and an encapsulation layer. The substrate is provided with a display area and a pad area. The plurality of light emitting devices are disposed in the display area of the substrate. The plurality of pads are disposed in the pad area of the substrate. The encapsulation layer covers the plurality of light emitting devices and does not cover the plurality of pads. The encapsulation has a warped portion adjacent to the pad area. A gap is provided between the warped portion and a substrate surface of the substrate. The gap has a gap height along a normal direction of the substrate surface. The gap height increases as it approaches the plurality of pads.

A display panel of the disclosure includes a substrate, a plurality of light emitting devices, a plurality of pads and an encapsulation layer. The substrate is provided with a display area, a buffer area and a pad area. The buffer area is located between the display area and the pad area. The plurality of light emitting devices are disposed in the display area of the substrate. The plurality of pads are disposed in the pad area of the substrate. The encapsulation layer covers the plurality of light emitting devices and does not cover the plurality of pads. The encapsulation has a warped portion adjacent to the pad area. A gap is provided between the warped portion and a substrate surface of the substrate. The encapsulation layer has a first thickness in the buffer area. The first thickness varies with increasing distance from the display area.

A manufacturing method of a display panel of the disclosure includes the following steps: providing a substrate, forming a patterned sacrificial layer on the substrate, forming an encapsulation layer on the substrate to cover a plurality of light emitting devices in a display area of the substrate and the patterned sacrificial layer, performing a laser cutting step on the encapsulation layer, and removing the patterned sacrificial layer to expose a plurality of pads in a pad area of the substrate. The patterned sacrificial layer covers the plurality of pads and does not cover the plurality of light emitting devices. The encapsulation layer has two break points overlapping the patterned sacrificial layer after the laser cutting step is completed. A portion of the encapsulation layer adjacent to the pad area forms a warped portion after the patterned sacrificial layer is removed. A gap is provided between the warped portion and a substrate surface of the substrate.

Based on the above, in a manufacturing method of a display panel according to an embodiment of the disclosure, prior to the formation of the encapsulation layer, a patterned sacrificial layer is formed to cover the plurality of pads in a pad area. Following the formation of the encapsulation layer, a laser cutting process is performed on a portion of the encapsulation layer located above the patterned sacrificial layer to form two break points, thereby enabling removal of the patterned sacrificial layer. Upon the removal of the patterned sacrificial layer, the plurality of pads are exposed and fewer functional film layers remain in the pad area, thereby improving the bonding yield or electrical test yield of the display panel in the back-end manufacturing process. Since the patterned sacrificial layer is removed after the encapsulation layer is formed, a portion of the encapsulation layer adjacent to the pad area forms a warped portion after the removal of the patterned sacrificial layer, and a gap is formed between the warped portion and the substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a display panel according to an embodiment of the disclosure.

FIGS. 2A to 2E are schematic cross-sectional views of a manufacturing process of the display panel in FIG. 1.

FIG. 3 is a schematic cross-sectional view of a display panel according to another embodiment of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

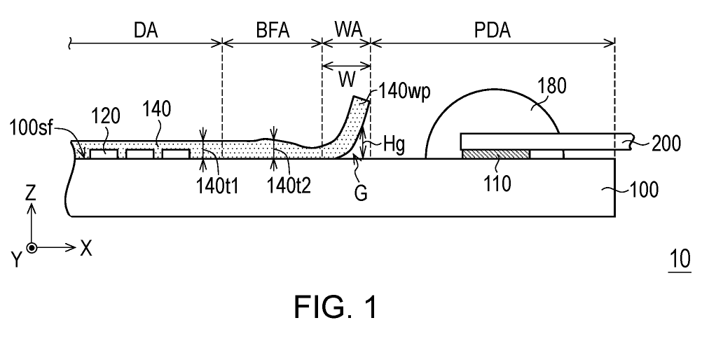

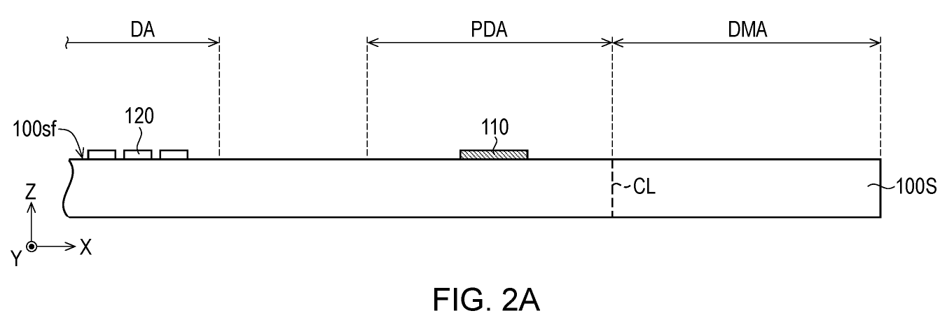

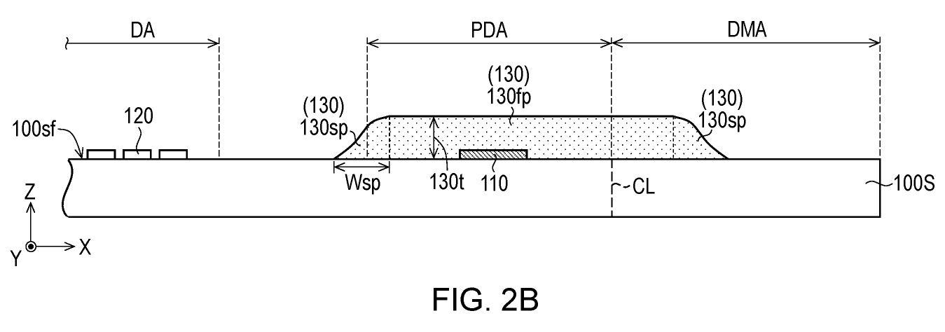

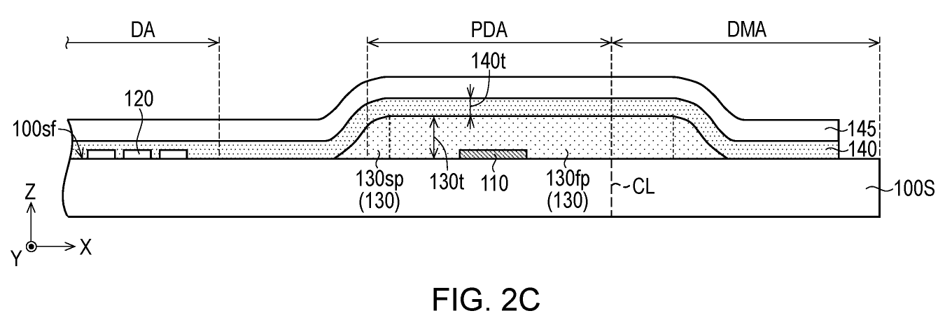

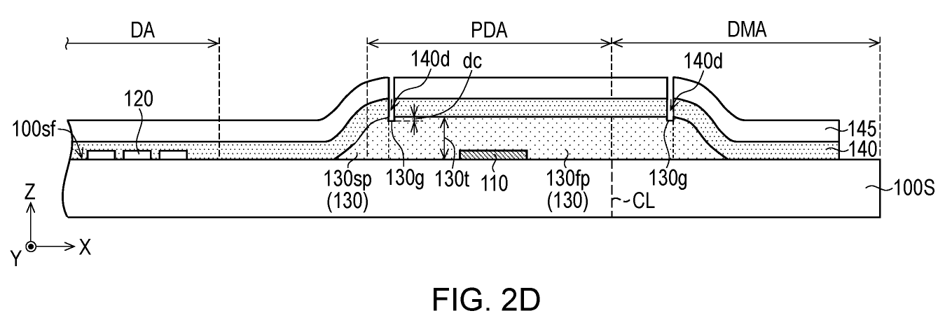

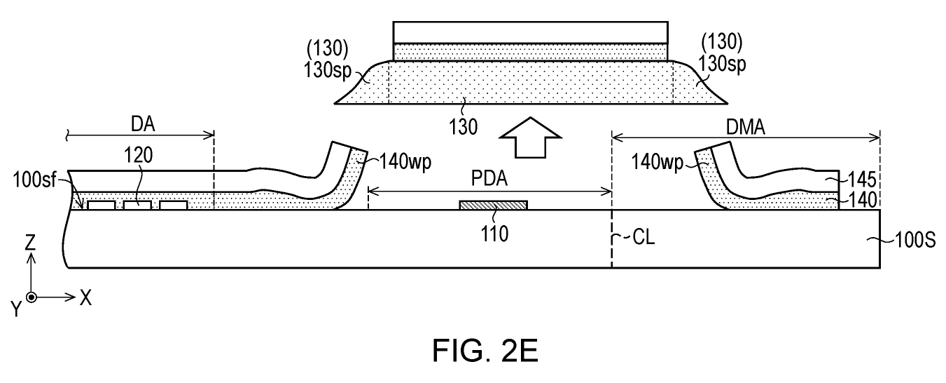

FIG. 1 is a schematic cross-sectional view of a display panel according to an embodiment of the disclosure. FIGS. 2A to 2E are schematic cross-sectional views of a manufacturing process of the display panel in FIG. 1. Referring to FIG. 1, a display panel 10 includes a substrate 100, a plurality of pads 110 and a plurality of light emitting devices 120. The plurality of pads 110 are disposed in a pad area PDA of the substrate 100. The plurality of light emitting devices 120 are disposed in a display area DA of the substrate 100. In the embodiment, the substrate 100 is, for example, a glass substrate, and a pixel circuit layer (not shown) is disposed thereon, but the disclosure is not limited thereto. In other embodiments, the substrate 100 may be a common circuit board in the technical field to which the disclosure belongs.

In the embodiment, the pad 110 can be used to bond a flexible circuit board 200, such as a chip on film (COF), and is covered by an encapsulation body 180, but the disclosure is not limited thereto. In order to perform an electrical test (cell test) in a back-end manufacturing process of the display panel 10, the pad area PDA of the display panel 10 may further be provided with pads (not shown) suitable for contact with probe pins of a testing machine.

Furthermore, the display panel 10 further includes an encapsulation layer 140 covering the plurality of light emitting devices 120 in the display area DA. It is first noted that, to enable the pads in the pad area PDA to perform their intended functions properly, such as the electrical bonding between the pads 110 and the flexible circuit board 200 (or the electrical contact between the pads and the test machine), the encapsulation layer 140 does not cover the pads 110 in the pad area PDA. In the embodiment, a variation of a thickness 140t1 of the encapsulation layer 140 in the display area DA is less than or equal to 2 μm, that is, the encapsulation layer 140 has a uniform thickness distribution in the display area DA. The aforementioned thickness 140t1 is, for example, the thickness of the encapsulation layer 140 along a normal direction (e.g., direction Z) of a substrate surface 100sf. Unless otherwise specified below, a thickness of a film layer is defined in the same direction, and the direction used to define the thickness will not be redundantly described.

It is particularly noted that the encapsulation layer 140 has a warped portion 140wp adjacent to the pad area PDA. A gap G is provided between the warped portion 140wp and the substrate surface 100sf of the substrate 100. The gap G has a gap height Hg along the normal direction (e.g., direction Z) of the substrate surface 100sf, and the gap height Hg increases as it approaches the pad area PDA. More specifically, an edge portion of the encapsulation layer 140 adjacent to the pad area PDA (i.e., the warped portion 140wp) gradually moves away from the substrate surface 100sf in a direction (e.g., direction X) from the display area DA toward the pad area PDA. In the embodiment, the distribution range of the warped portion 140wp may be defined as a warped area WA of the substrate 100. Preferably, a ratio of the maximum value of the gap height Hg of the gap G to the thickness 140t1 of the encapsulation layer 140 in the display area DA is greater than 1.1. a width W of the warped portion 140wp along an arrangement direction (e.g., direction X) of the display area DA and the pad area PDA may be greater than or equal to 0.1 mm and less than or equal to 3 mm.

In the embodiment, the substrate 100 may further include a buffer area BFA between the display area DA and the pad area PDA. More specifically, the buffer area BFA is located between the warped area WA and the display area DA. In the embodiment, a thickness 140t2 of the encapsulation layer 140 in the buffer area BFA varies with increasing distance from the display area DA, and an absolute difference between the thickness 140t2 and the thickness 140t1 is greater than 4 μm. For example, a thickness of the encapsulation layer 140 in a portion of the buffer area BFA may be greater than the thickness 140t1 thereof in the display area DA, and a thickness of the encapsulation layer 140 in another portion of the buffer area BFA may be less than the thickness 140t1 thereof in the display area DA. That is, the encapsulation layer 140 has a non-uniform thickness distribution in the buffer region BFA.

The following is an exemplary description of a manufacturing method of the display panel 10.

Referring to FIG. 2A, first, a substrate 100S is provided. In the embodiment, the substrate 100S is provided with a display area DA, a pad area PDA and a dummy area DMA. The display area DA is provided with a plurality of light emitting devices 120. The pad area PDA is provided with a plurality of pads 110. The dummy area DMA is located at a side of the pad area PDA facing away from the display area DA. For example, a test or detection circuit used in a manufacturing process may be disposed in the dummy area DMA, but the disclosure is not limited thereto. It is first noted that a boundary between the pad area PDA and the dummy area DMA of the substrate 100S may define a cutting line CL in a subsequent manufacturing process.

Next, forming a patterned sacrificial layer 130 on the substrate 100S, as shown in FIG. 2B. The patterned sacrificial layer 130 is formed in the pad area PDA and a portion of the dummy area DMA. More specifically, the patterned sacrificial layer 130 covers the plurality of pads 110 in the pad area PDA and does not cover the plurality of light emitting devices 120 in the display area DA. The material of the patterned sacrificial layer 130 includes, for example, a peelable adhesive. For example, a screw valve (not shown) may be used to dispense the peelable adhesive along a direction Y within the pad area PDA to form the patterned sacrificial layer 130 of the embodiment, but the disclosure is not limited thereto. In the embodiment, the patterned sacrificial layer 130 may have a flat portion 130fp and two sloped portions 130sp connecting the flat portion 130fp. One sloped portion 130sp is located between the flat portion 130fp and the display area DA, and the other sloped portion 130sp is located in the dummy area DMA.

It should be noted that a portion of the patterned sacrificial layer 130 with a slope relative to the substrate 100S and less than or equal to 0.2 may be defined as the aforementioned flat portion 130fp, and the other portion with a slope greater than 0.2 may be defined as the aforementioned sloped portion 130sp. Preferably, a width Wsp of the sloped portion 130sp along an arrangement direction (e.g., direction X) of the display area DA and the pad area PDA may be less than 800 μm. Accordingly, the configuration flexibility of the patterned sacrificial layer 130 on the substrate 100S may be increased, for example, the patterned sacrificial layer 130 may be coated as close to the display area DA as possible without covering the display area DA.

It is first noted that in order to avoid issues of breakage and residue when removing the patterned sacrificial layer 130 in a subsequent process, a thickness 130t of the patterned sacrificial layer 130 is preferably greater than or equal to 50 μm and less than or equal to 300 μm.

Referring to FIG. 2C, after the patterned sacrificial layer 130 is formed, forming an encapsulation layer 140 on the substrate 100S to cover the plurality of light emitting devices 120 and the patterned sacrificial layer 130. For example, in the embodiment, the encapsulation layer 140 may be first formed on a flexible substrate 145 and then attached to the substrate 100S by means of a lamination process, wherein the material of the flexible substrate 145 is, for example, polyethylene terephthalate (PET), but the disclosure is not limited thereto. In other embodiments, the encapsulation layer 140 may be formed on the substrate 100S by a coating method. A thickness 140t of the encapsulation layer 140 may be, for example, less than or equal to 50 μm.

Preferably, a ratio of the thickness 130t of the patterned sacrificial layer 130 to the thickness 140t of the encapsulation layer 140 may be greater than or equal to 1.5 and less than or equal to 20. Accordingly, the success rate of removing the patterned sacrificial layer 130 in subsequent processes can be increased.

After the encapsulation layer 140 is formed, performing a laser cutting step on the encapsulation layer 140 so that the encapsulation layer 140 has two break points 140d, as shown in FIG. 2D. It is particularly noted that the two break points 140d of the encapsulation layer 140 overlap the patterned sacrificial layer 130 along a normal direction (e.g., direction Z) of the substrate surface 100sf. More specifically, the two break points 140d overlap the flat portion 130fp of the patterned sacrificial layer 130. On the other hand, the two break points 140d completely penetrate the encapsulation layer 140. In other words, a portion of the encapsulation layer 140 above the patterned sacrificial layer 130 and located between the two break points 140d is structurally separated from the other portion of the encapsulation layer 140. It is particularly noted that if the encapsulation layer 140 is not completely cut during the laser cutting process, there is an increased risk that the portion of the encapsulation layer 140 located above the patterned sacrificial layer 130 cannot be removed in subsequent processes.

In the embodiment, the laser cutting process of the encapsulation layer 140 also simultaneously forms two cutting grooves 130g on the patterned sacrificial layer 130. That is, the two cutting grooves 130g overlap the two break points 140d of the encapsulation layer 140 along the direction Z, respectively. Preferably, a percentage of a cutting depth dc of the cutting groove 130g along the direction Z to the thickness 130t of the patterned sacrificial layer 130 is less than 10%. Accordingly, the driving circuit (not shown) on the substrate 100S can be protected from laser damage.

It should be understood that, in the embodiment, a flexible substrate 145 is further provided on a side of the encapsulation layer 140 facing away from the substrate 100S. Therefore, during the laser cutting process, two break points that completely penetrate the flexible substrate 145 are formed on the patterned sacrificial layer 130, and the two break points overlap the two break points 140d of the encapsulation layer 140 along the direction Z, respectively.

After the laser cutting process is completed, removing the patterned sacrificial layer 130 to expose the plurality of pads 110, as shown in FIG. 2E. It should be noted that a portion of the encapsulation layer 140 overlapping the sloped portion 130sp of the patterned sacrificial layer 130 along the direction Z will be lifted during the removal process of the patterned sacrificial layer 130, as the sloped portion 130sp moves away from the substrate 100S. After the patterned sacrificial layer 130 is removed, the portion of the encapsulation layer 140 forms a warped portion 140wp.

In order to improve the removal success rate of the patterned sacrificial layer 130, the Young's modulus of the encapsulation layer 140 should be greater than the Young's modulus of the patterned sacrificial layer 130. Preferably, a ratio of the Young's modulus of the encapsulation layer 140 to the Young's modulus of the patterned sacrificial layer 130 may be less than 15.

After the patterned sacrificial layer 130 is removed, performing a cutting process on the substrate 100S to remove a portion of the substrate 100S located in the dummy area DMA, and form the substrate 100 as shown in FIG. 1. For example, during the cutting process, a cutter (not shown) cut along a cutting line CL (i.e., a boundary between the pad area PDA and the dummy area DMA), but the disclosure is not limited thereto. Next, a flexible circuit board 200 is electrically bonded to the plurality of pads 110 on the substrate 100, and the pads 110 and a portion of the flexible circuit board 200 are encapsulated with an encapsulation body 180. On the other hand, the flexible substrate 145 on the encapsulation layer 140 in FIG. 2E may be removed.

At this point, the fabrication of the display panel 10 in FIG. 1 is completed.

Referring to FIG. 1, the encapsulation layer 140 of the display panel 10 manufactured by the above method has a warped portion 140wp adjacent to the pad area PDA. A gap G is provided between the warped portion 140wp and the substrate surface 100sf of the substrate 100. The gap G has a gap height Hg along the normal direction of the substrate surface 100sf, and the gap height Hg increases as it approaches the plurality of pads 110.

Another embodiment is provided below to describe the invention in detail, where the same reference numerals denote the same or like components, and descriptions of the same technical contents are omitted. The aforementioned embodiment may be referred for descriptions of the omitted parts, and detailed descriptions thereof are not repeated in the following embodiment.

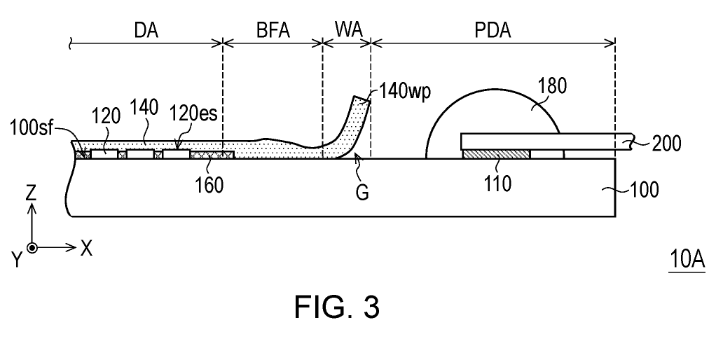

FIG. 3 is a schematic cross-sectional view of a display panel according to another embodiment of the disclosure. Referring to FIG. 3, compared to the display panel 10 of FIG. 1, a display panel 10A of the embodiment may further include a light absorbing layer 160 disposed in the display area DA of the substrate 100 and located between the plurality of light emitting devices 120, wherein the encapsulation layer 140 further covers the light absorbing layer 160. More specifically, the light absorbing layer 160 covers the substrate surface 100sf of the substrate 100 and does not cover a light emitting surface 120es of each of the plurality of light emitting device 120. Accordingly, the reflectance of ambient light on the substrate 100 can be reduced, thereby improving the display contrast of the display panel 10A.

Since the manufacturing steps of the display panel 10A, except for the light absorbing layer 160, are similar to those of the display panel 10 in FIG. 1, please refer to the relevant paragraphs of the aforementioned embodiment for detailed description, which will not be repeated here.

To sum up, in a manufacturing method of a display panel according to an embodiment of the disclosure, prior to the formation of the encapsulation layer, a patterned sacrificial layer is formed to cover the plurality of pads in a pad area. Following the formation of the encapsulation layer, a laser cutting process is performed on a portion of the encapsulation layer located above the patterned sacrificial layer to form two break points, thereby enabling removal of the patterned sacrificial layer. Upon the removal of the patterned sacrificial layer, the plurality of pads are exposed and fewer functional film layers remain in the pad area, thereby improving the bonding yield or electrical test yield of the display panel in the back-end manufacturing process. Since the patterned sacrificial layer is removed after the encapsulation layer is formed, a portion of the encapsulation layer adjacent to the pad area forms a warped portion after the removal of the patterned sacrificial layer, and a gap is formed between the warped portion and the substrate.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display panel, comprising:
a substrate, provided with a display area and a pad area;
a plurality of light emitting devices, disposed in the display area of the substrate;
a plurality of pads, disposed in the pad area of the substrate; and
an encapsulation layer, covering the plurality of light emitting devices and not covering the plurality of pads, wherein the encapsulation has a warped portion adjacent to the pad area, a gap is provided between the warped portion and a substrate surface of the substrate, the gap has a gap height along a normal direction of the substrate surface, and the gap height increases as it approaches the plurality of pads.

2. The display panel according to claim 1, wherein the encapsulation layer has a first thickness in the display area, and a variation of the first thickness in the display area is less than or equal to 2 μm.

3. The display panel according to claim 2, wherein the substrate is further provided with a buffer area between the display area and the pad area, the encapsulation layer has a second thickness in the buffer area, the second thickness varies with increasing distance from the display area, and an absolute difference between the first thickness and the second thickness is greater than 4 μm.

4. The display panel according to claim 2, wherein a ratio of a maximum value of the gap height to the first thickness is greater than 1.1.

5. The display panel according to claim 1, wherein the display area and the pad area are arranged along a first direction, and a width of the warped portion along the first direction is greater than or equal to 0.1 mm and less than or equal to 3 mm.

6. The display panel according to claim 1, further comprising:
a light absorbing layer, disposed in the display area of the substrate and located between the plurality of light emitting devices, wherein the encapsulation layer further covers the light absorbing layer.

7. A display panel, comprising:
a substrate, provided with a display area, a buffer area and a pad area, wherein the buffer area is located between the display area and the pad area;
a plurality of light emitting devices, disposed in the display area of the substrate;
a plurality of pads, disposed in the pad area of the substrate; and
an encapsulation layer, covering the plurality of light emitting devices and not covering the plurality of pads, wherein the encapsulation layer has a warped portion adjacent to the pad area, a gap is provided between the warped portion and a substrate surface of the substrate, the encapsulation layer has a first thickness in the buffer area, and the first thickness varies with increasing distance from the display area.

8. The display panel according to claim 7, wherein the gap has a gap height along a normal direction of the substrate surface, and the gap height increases as it approaches the plurality of pads.

9. The display panel according to claim 8, wherein the encapsulation layer has a second thickness in the display area, and a ratio of a maximum value of the gap height to the second thickness is greater than 1.1.

10. The display panel according to claim 7, wherein the encapsulation layer has a second thickness in the display area, and a variation of the first thickness in the display area is less than or equal to 2 μm.

11. The display panel according to claim 10, wherein an absolute difference between the first thickness and the second thickness is greater than 4 μm.

12. The display panel according to claim 7, wherein the display area and the pad area are arranged along a first direction, and a width of the warped portion along the first direction is greater than or equal to 0.1 mm and less than or equal to 3 mm.

13. The display panel according to claim 7, further comprising:
a light absorbing layer, disposed in the display area of the substrate and located between the plurality of light emitting devices, wherein the encapsulation layer further covers the light absorbing layer.

14. A manufacturing method of a display panel, comprising:
providing a substrate, wherein a display area of the substrate is provided with a plurality of light emitting devices, and a pad area of the substrate is provided with a plurality of pads;
forming a patterned sacrificial layer on the substrate, wherein the patterned sacrificial layer covers the plurality of pads and does not cover the plurality of light emitting devices;
forming an encapsulation layer on the substrate to cover the plurality of light emitting devices and the patterned sacrificial layer;
performing a laser cutting step on the encapsulation layer so that the encapsulation layer has two break points overlapping the patterned sacrificial layer; and
removing the patterned sacrificial layer to expose the plurality of pads, wherein a portion of the encapsulation layer adjacent to the pad area forms a warped portion after the patterned sacrificial layer is removed, and a gap is provided between the warped portion and a substrate surface of the substrate.

15. The manufacturing method of the display panel according to claim 14, wherein the Young’s modulus of the encapsulation layer is greater than the Young’s modulus of the patterned sacrificial layer.

16. The manufacturing method of the display panel according to claim 15, wherein a ratio of the Young’s modulus of the encapsulation layer to the Young’s modulus of the patterned sacrificial layer is less than 15.

17. The manufacturing method of the display panel according to claim 14, wherein the patterned sacrificial layer and the encapsulation layer respectively have a first thickness and a second thickness along a normal direction of a substrate surface of the substrate, and a ratio of the first thickness to the second thickness is greater than or equal to 1.5 and less than or equal to 20.

18. The manufacturing method of the display panel according to claim 14, wherein after the laser cutting step is completed, the patterned sacrificial layer has two cutting grooves overlapping the two break points of the encapsulation layer, the two cutting grooves each have a cutting depth along a normal direction of a substrate surface of the substrate, the patterned sacrificial layer has a thickness along the normal direction of the substrate surface, and a percentage of the cutting depth to the thickness is less than 10%.

19. The manufacturing method of the display panel according to claim 14, wherein the patterned sacrificial layer has a flat portion and a sloped portion connected to each other, the sloped portion is located between the flat portion and the display area, a slope of the flat portion relative to the substrate is less than or equal to 0.2, a slope of the sloped portion relative to the substrate is greater than 0.2, and a width of the sloped portion along an arrangement direction of the display area and the pad area is less than 800 μm.

20. The manufacturing method of the display panel according to claim 19, wherein the two break points of the encapsulation layer overlap the flat portion of the patterned sacrificial layer.
